(19) United States
(12) Patent Application Publication
(10) Pub. No.: US 2008/0210934 A1
(43) Pub. Date: Sep. 4, 2008

(54) Semiconductor Device Using Titanium Dioxide as Active Layer and Method for Producing Semiconductor Device

(75) Inventors: Hideomi Koinuma, Kanagawa (JP); Yuji Matsumoto, Kanagawa (JP); Masao Katayama, Kanagawa (JP)

Correspondence Address: GREENBLUM & BERNSTEIN, P.L.C., 1950 ROLAND CLARKE PLACE, RESTON, VA, 20191, US

(73) Assignees: TOKYO INSTITUTE OF TECHNOLOGY, Tokyo (JP); JAPAN SCIENCE AND TECHNOLOGY AGENCY, Saitama (JP)

(21) Appl. No.: 11/909,119

(22) PCT Filed: Feb. 23, 2006
(86) PCT No.: PCT/JP2006/303274

§ 371 Date: Dec. 19, 2007

(30) Foreign Application Priority Data
Mar. 25, 2005 (JP) 2005-088733

(51) Int. Cl. H01L 29/10; H01L 21/00

(52) U.S. Cl. 257/43; 438/104; 257/E29.043; 257/E21.001

(57) ABSTRACT

Object: To provide a semiconductor device using titanium dioxide as an active layer and a method for producing thereof.

Means for Solving the Problems: The semiconductor device 10 according to the present invention includes TiO₂ as an active layer thereof. The semiconductor device 10 according to the present invention includes a gate electrode 20, a TiO₂ layer 12 which functions as a semiconductor active layer and forming a channel, a source electrode and a drain electrode being electrically connected to the TiO₂ layer, and an insulating film formed between the gate electrode and the TiO₂ layer. The TiO₂ layer 12 may be a single crystal substrate including a Rutile or Anatase structure which has a step-terrace structure. The TiO₂ layer 12 may be a vapor deposition film of TiO₂. Further the present invention provides a method for producing the semiconductor device using titanium dioxide as the active layer.

### FIELD OF THE INVENTION

The present invention relates to a semiconductor device, and more particularly, relates to a semiconductor device using titanium dioxide (TiO₂) as an active layer and a method for producing thereof.

### BACKGROUND ART

Recently, field effect type semiconductors are used to form active matrix arrays and to provide a display device as well as arithmetic logic units of an information processing apparatus. As the active layer in such field effect type semiconductor device, semiconductor active materials, such as amorphous silicon, single crystal silicon, zinc oxide (ZnO), etc, have been known so far. Because the semiconductor materials, such as amorphous silicon, single crystal silicon and ZnO, have a feature in which photo-carriers are generated by absorbing photons with given wavelength as well as voltage application, and then it is necessary to form an optical shield film to shield the active layer optically in order to provide excellent field effect characteristics.

For providing semiconductor device, it is believed that mobility of carriers in the active layer, which is not as high as the mobility of ZnO provides sufficient functions. Also, above amorphous silicon, single crystal silicon, zinc oxide (ZnO), etc may be formed into the active layer by using various deposition methods, however, it is not sufficiently enough from the points including productivity, costs, large size applicability as well as environmental load by the use of heavy metal, which are to require additional production process to form an optical shield film in order to prevent from generating its photo-carriers; the production performances, production costs, easiness for enlargement of the area size and environmental load.

On the other hand, titanium dioxide (TiO₂) recently applied to large area members such as building materials using the photo-catalytic property thereof because titanium dioxide does not include heavy metals, leading to smaller environmental loading. Although titanium dioxide is well known to generate photo-carriers, its photo-carriers generation efficiency is much less than that of silicon and ZnO, etc. Thus it is expected that when titanium dioxide could be used as an active layer in a field effect type semiconductor device, a displayable structured material, such as a novel large area glass or panel including field effect type semiconductor devices, and a large-area displaying devices may be provided. In addition, it is thought that the field effect type semiconductor device using titanium dioxide is expect to provide excellent functions without any optical shield layers, and that structure materials with reduced cost and improved optical transparency could be provided while lowering costs accompanying cut down on the production process.

The inventors investigated formation of a TiO₂ film and characteristics thereof, and have been disclosed an atomic scale surface control technique of a TiO₂ single crystal substrate in Patent Literature 1 (Japanese Patent Laid Open No. 2004-288767) for instance. On the other hand, while various studies on application of TiO₂ as photo-catalyst, there is almost no study for adapting the semiconductor performance of TiO₂ to active layer in field effect type semiconductors. Also, Patent Literature 2 (Japanese Patent Open Laid No. 2002-198539) discloses a thin film field effect transistor using organic-inorganic hybrid semiconductor. Patent Literature 2 discloses the points to form organic-inorganic hybrid semiconductors from organic metal compounds including tin atom, and to use TiO₂ as a gate insulator, however Patent Literature 2 does not disclose any points to use TiO₂ in itself as a semiconductor.

Patent Literature 1: Japanese Patent Laid-Open No. 2004-288767

Patent Literature 2: Japanese Patent Laid-Open No. 2002-198539

### DISCLOSURE OF INVENTION

### Problems to be Solved by the Invention

The present invention has been made by considering the above conventional art, and the present invention has an object to provide a field effect type semiconductor device using titanium dioxide (TiO₂) as an active layer and a method for producing thereof.

### Means for Solving Problem

In view of the above conventional art, the present inventors turned their attention to the semiconductor active property of TiO₂, and examined based on an idea that when TiO₂ could be used as an active layer to form a channel and electronic characteristics thereof could be controlled by electric field, a structured element having rather large area and excellent optical properties with low production cost may be provided. As a result, the present inventors completed the present invention by finding that the semiconductor properties strongly depend on surface quality, and the carrier density in TiO₂ may be controlled by electric field, by controlling surface quality at the atomic level. Furthermore, the present inventors have reached the present invention by finding that the characteristics of the semiconductor device using TiO₂ as the active layers, is strongly depends on the insulating film and is controllable in response to the compositions of the insulating layer.

According to the first aspect of the present invention, there is provided a field effect type semiconductor device including TiO₂ as an active layer thereof, the semiconductor device including a gate electrode, a TiO₂ layer for forming a channel, a source electrode and a drain electrode being electrically connected to the TiO₂ layer, and an insulating film formed between the gate electrode and the TiO₂ layer.

Also, according to the present invention, the TiO₂ layer may preferably include a Rutile or Anatase structure having a step-terrace structure, or a Rutile or Anatase structure having an ultra-smooth surface thereof. The TiO₂ layer may be a vapor deposition film of TiO₂ . The insulating film of the present invention may be composed from a plurality of oxide layers having different oxygen content ratios each other, and one of the oxide layers may have smaller the oxygen content ratio than other being formed adjacent to the TiO₂ layer.

According to the second aspect of the present invention, there is provided a method for producing a field effect type semiconductor device including TiO₂ as an active layer thereof, the method including the steps of, subjecting a surface treatment to a semiconductor layer including TiO₂ , forming a source electrode and a drain electrode being electrically connected to the semiconductor layer subjected the surface treatment, forming an insulating film on the semiconductor layer, and forming a gate electrode on the insulating film.

In the present invention, The insulating film may be composed from a plurality of oxide layers having different oxygen content ratios each other, and the step of forming the insulating film may include a sub-step of forming one of the oxide layers having smaller the oxygen content ratio than other adjacent to the semiconductor layer. In the present invention, the step of subjecting the surface treatment may include a sub-step of providing a step-terrace structure into the semiconductor layer.

According to the third aspect of the present invention, there is provided a method for producing a field effect type semiconductor device including TiO₂ as an active layer thereof, the method including the steps of, depositing a semiconductor layer including TiO₂ on a substrate, forming a source electrode and a drain electrode being electrically connected to the semiconductor layer, forming an insulating film on the semiconductor layer, and forming a gate electrode on the insulating film.

In the present invention, the insulating film may be composed from a plurality of oxide layers having different oxygen content ratios each other, and the step of forming the insulating film may include a sub-step of forming one of the oxide layers having smaller the oxygen content ratio than other adjacent to the semiconductor layer.

According to the forth aspect of the present invention, there is provided a method for producing a field effect type semiconductor device including TiO₂ as an active layer thereof, the method including the steps of, forming a source electrode and a drain electrode on a dielectric substrate, forming a semiconductor layer including TiO₂ , the semiconductor layer being electrically connected to the source electrode and the drain electrode, forming a gate insulating film adjacent to the semiconductor layer, and forming a gate electrode on the gate insulating film.

Also, in the present invention, the step of forming the semiconductor layer including TiO₂ may include a sub-step of modulating an oxygen partial pressure intermittently. The method may include steps of, depositing TiO₂ under the lower oxygen partial pressure condition within the sub-step for modulating the oxygen partial pressure intermittently, and annealing deposited TiO₂ under the higher oxygen partial pressure condition within the sub-step of modulating the oxygen partial pressure intermittently.

### BEST MODE FOR CARRYING OUT THE INVENTION

Hereinafter, the present invention will be described in detail with referring to drawings, however, the present invention is not limited by the specific embodiments described below. FIG. 1 shows the structure of the semiconductor device according to the first embodiment of the present invention. FIG. 1(a) shows the cross-sectional view of the semiconductor device and FIG. 1(b) depicts the top view thereof. The cross-section presented in FIG. 1(a) corresponds to the cross-section structure sliced along with the plane represented by the line A-A. The semiconductor device 10 of the first embodiment of the present invention, includes the substrate 12, the source electrode 14 formed on the substrate 12, the drain electrode 16, the gate insulating film 18 formed on the source electrode 14 and the drain electrode 16, and the gate electrode 20 formed on the gate insulating film 18. The substrate 12 provides TiO₂ layer, more particularly, a TiO₂ single crystal substrate is used in the first embodiment of the present invention. The single crystal substrate having Rutile type crystal structure with (1 1 0) surface may be used.

The index faces may be (1 0 0), (0 0 1), (1 1 1) and (1 0 1) as well as (1 1 0) surface and is not limited particular index faces. In the present invention, it is necessary that a commercially provided single crystal substrate is subjected to etch using an etchant so as to improve the surface condition thereof when the commercially provided single crystal substrate is used. Any known etchants such as hydrofluoric acid, diluted hydrofluoric acid solution, hydrofluoric acid—phosphoric acid—nitric acid mixture, etc., may be used as far as the etchant could etch TiO₂ in the present invention.

The source electrode 14 and the drain electrode 16 may be formed by photolithography, or any physical deposition methods such as vapor deposition, sputtering, laser abrasion, etc., with appropriate masks, and Al, W, Ti, Ni or Mo, or any alloys thereof may be used as the electrode material thereof. It is preferable that the thicknesses of the source electrode 14 and the drain electrode 16 are within the range from 10 nm to 20 nm. Although the thicknesses are approximately 15 nm as for the first embodiment shown in FIG. 1, however, there is no limitation for the thickness, and any thickness may be used as far as it provides appropriate connectivity. As for the first embodiment of the present invention shown in FIG. 1, no ohmic contact layer is formed to achieve ohmic contact particularly, however, in relation with a particular electrode material, an appropriate ohmic layer may be employed at the interface between the substrate 12, adjacent to the source electrode 14 and the drain electrode 16, and the gate insulating film 18 described hereinafter, in the present invention.

The gate insulating film 18 is formed on the source electrode 14 and the drain electrode 16, and the film of amorphous LaAlO₃ being deposited by pulse laser deposition (PLD) method is used as the gate insulating film 18 in the first embodiment of the present invention. In the present invention, magnesium oxide, silicon nitride, LaAlO₃, tantalum pentoxide, yttrium trioxide, silicon dioxide, aluminum oxide, calcium oxide, boron trioxide, beryllium oxide, barium oxide, or any admixture thereof may be used as the material that used to form the insulating film 18. As for the deposition method thereof, CVD (Chemical Vapor Deposition) method, sputtering method as well as laser abrasion method may be employed. Although the thickness of the gate insulating film is approximately 450 nm as for the first embodiment shown in FIG. 1, however, the thickness of the gate insulating film may be designed within the range from approximately 200 nm to approximately 1000 nm, more preferably from approximately 300 nm to approximately 900 nm in the present invention. Furthermore in the present invention, the thickness of the gate insulating film may be varied from about 50 nm to about 10 μm (micro meter) in response to the employed dielectric material and the device characteristics.

The gate electrode 20 is formed on the gate insulating film 18 by a masking method. The gate electrode 20 is formed from Al with approximately 15 nm thick in the first embodiment of the present invention, however, as the gate electrode, metals including Al, W, Ti, Ni or Mo, or any alloys thereof may be available and may be formed in the range from approximately 10 nm to approximately 20 nm in thickness. Furthermore, the semiconductor device according to the present invention may have a passivation film composed from materials including poly-methacrylate, poly-styrene, poly-carbonate, silicone, silicon dioxide, silicon nitride, etc., in order to protect the elements shown in FIG. 1.

The FIG. 1(b) shows top view of the semiconductor device of the first embodiment according to the present invention. The size of the gate insulating film 18 of the semiconductor device 10 is approximately 700 μm (micro meter) by 1100 μm (micro meter), and the distance between the source and drain electrodes is 200 μm (micro meter), and the length of the sides of the source electrode 14 and the drain electrode 16, opposed each other, are 500 μm (micro meter). Each structure is prepared by vacuum vapor deposition and PLD methods with masks.

FIG. 2 shows the second embodiment of the semiconductor device according to the present invention. FIG. 2(a) shows the cross-sectional view thereof and FIG. 2(b) depicts the top view thereof. The cross-section structure corresponds to that sliced along with the plane represented by the line A-A in the FIG. 2(b). Since the semiconductor device of the second embodiment according to the present invention has the same structure as the embodiment explained in FIG. 1 with the exception that the gate insulating film 18 is formed by laminated a plurality of materials to improve insulation thereof, the detailed structure of the insulating film 18 will be explained hereinafter. The insulating film 18 of the semiconductor device shown in FIG. 2 is formed with the first insulating film 18a and the second insulating film 18b. Both the first insulating film and the second insulating film may be formed from above described oxide films, and the thickness of the first insulating film may be within the range from 1 nm to 50 nm, more preferably from 1 nm to 30 nm and the most preferable region may be from 1 nm to 20 nm. The deposition of the first insulating film 18a in the particular embodiment of the present invention may be formed by laser abrasion method, however any methods such as CVD (Chemical Vapor Deposition) may be employed as far as that enable deposition of the oxide, however, the present invention does not limited by the thickness described above.

The second insulating film 18b of the second embodiment according to the present invention may be formed by using the same oxide as the first insulating film. However, in the present invention, the tendency, in which the oxygen content ratio (molar ratio) of the oxide that constitutes the first insulating film was lower than the oxide that constitutes the second insulating film, was found to be preferable in order to provide good switching performance. The thickness of the second insulating film may be applied within the range from 300 nm to 1000 nm, more preferably, from 300 nm to 900 nm. The total thickness of both the first insulating film and second insulating film may be within the range from approximately 300 nm to approximately 1000 nm.

FIG. 3 shows the third embodiment of the semiconductor device according to the present invention. As similar to FIG. 1 and FIG. 2, FIG. 3(a) shows the corresponding cross-section structure sliced along with the plane represented by the line A-A in the top view shown in FIG. 3(b). In the embodiment shown in FIG. 3, the TiO₂ film 22 is deposited on the substrate 12 by using PVD, laser abrasion or CVD methods. Then, the substrate 12 may be subjected to etching with an etchant or to heat treatment under the range from 500 Celsius degrees to 900 Celsius degrees. As the substrate 12 in the embodiment shown in FIG. 3, LaAlO₃ single crystal substrate may be used. In the embodiment shown in the FIG. 3, glass materials including soda-lime glass with a silica barrier layer, borosilicate glass, alumino-borosilicate glass, low alkali borosilicate glass, quartz glass, fused silica, etc., a silicon wafer, a GaAs wafer and a TiO₂ single crystal substrate may be employed as the substrate 12 as well as a LaAlO₃ single crystal substrate, however there is no limitation for the substrate 12 as far as the excellent TiO₂ film may be provided. In the case where TiO₂ film was formed by the vapor deposition method, the thickness of the TiO₂ film may be within the range from 10 nm to 1 μm (micro meter), more preferably, from 10 nm to 50 nm. On the TiO₂ film formed by the vapor deposition method, a plurality of gate insulating films may be formed to provide the semiconductor device as explained by referring to FIG. 2.

FIG. 4 shows the first embodiment of the production method of the semiconductor device according to the present invention. In the production method shown in FIG. 4, first, the TiO₂ single crystal substrate is prepared (FIG. 4(a)), and after the etching in the case where the substrate was subject to etching with the etchant, the source electrode 14 and the drain electrode 16 are deposited on the substrate 12 by using an appropriate mask or a photolithography methods (FIG. 4(b)). Thereafter, the gate insulating film 18 is formed by using the mask or the photolithography methods in a similar manner. And then, the gate electrode 20 is deposited on the gate insulating film 18 by the similar film formation method to provide the semiconductor device according to the present invention. And then, the passivation film may be formed to provide the semiconductor device according to the present invention depending on particular requirements.

FIG. 5 shows the second embodiment of the production method of the semiconductor device according to the present invention. In the second embodiment of the production method, after subjecting the TiO₂ single crystal substrate to etching when necessary (FIG. 5(a)), the source electrode 14 and the drain electrode 16 are formed by using the appropriate mask or the photolithography methods (FIG. 5(b)). Then, the first gate insulating film 18a is deposited (FIG. 5(c)), and then the second gate insulating film is deposited (FIG. 5(d)). Thereafter, the gate electrode is formed on the prepared second gate insulating film 18b to be semiconductor device (FIG. 5(e)).

Further in the present invention, the source electrode and the drain electrode may be formed below the TiO₂ layer. To produce the semiconductor device with such structure, first, the source electrode and the drain electrode are formed from an electrically conductive material, such as metal materials, on the dielectric substrate such as glass materials including soda-lime glass with a silica barrier layer, borosilicate glass, alumino-borosilicate glass, low alkali borosilicate glass, quartz glass, fused silica, etc., a silicon wafer, a GaAs wafer and LaAlO₃, and then the semiconductor layer including TiO₂ is formed thereon. After that, the gate insulating film is formed as explained hereinbefore, and the gate electrode is formed on the prepared gate insulating film to provide. The pattering thereof may be achieved by any known methods such as contact mask method or photolithography. Since TiO₂ in the present invention has a relatively low degree of photo-carrier generations, even the semiconductor device having staggered type structures may give a semiconductor active property without any optical shield layers.

FIG. 6 shows the third embodiment of the production method of the semiconductor device according to the present invention. In the production method shown in the FIG. 6, first, the TiO₂ film is formed on the substrate 12 to form the active layer (FIG. 6(a)). In the embodiment, as for the substrate, glass materials including soda-lime glass with a silica barrier layer, borosilicate glass, alumino-borosilicate glass, low alkali borosilicate glass, quartz glass, fused silica, etc., a silicon wafer, a GaAs wafer and a TiO₂ single crystal substrate as well as LaAlO₃ single crystal substrate may be employed as explained hereinbefore.

In the present invention, it was found that the channel characteristics of TiO₂ could be improved by modulating the oxygen partial pressure from lower to higher, vice versa during the TiO₂ film deposition, in order to improve the oxygen defects in the TiO₂ film. In the deposition method by oxygen intermittent modulation according to the present invention, the deposition of TiO₂ is subjected under the lower oxygen partial pressure, and the annealing of the deposited TiO₂ film is subjected under relatively higher oxygen partial pressure. Thereafter, TiO₂ are continuously deposited on the annealed TiO₂ film. The pressure corresponds to lower oxygen partial pressure may be within the range from 1.33×10⁻⁷ Pa to about 1.33 Pa; the pressure corresponds to higher oxygen partial pressure may be within the range from 1.3×10⁻⁴ Pa to 1.33×10³ Pa; and more preferably, the lower oxygen partial pressure may be within the range from 1.33×10⁻⁴ Pa to about 1.3 Pa. The higher oxygen partial pressure may be within the range from 0.013 Pa to about 13 Pa and the higher oxygen partial pressure may more preferably, be within the range from 0.013 to 1.3 Pa.

As for the duration under the lower oxygen partial pressure and the duration under the higher oxygen partial pressure, the ratio between the duration under the lower oxygen partial pressure and the duration under the higher oxygen partial pressure (3:5) may be within the range of 10:1 to 1:10, and in consideration of the film formation rate, the duration under the higher oxygen partial pressure may be within the range of 1:1 to 1:5, further in consideration of quality and efficiency thereof, be within the range of 1:1 to 1:3.

Then, the source electrode and the drain electrode are formed on the prepared TiO₂ film (FIG. 6(b)), and the gate insulating film 18 is formed (FIG. 6(c)). In the third embodiment according to the present invention also, the plurality of gate insulating films is allowed to laminate to form the gate insulating film 18 as explained with FIG. 5. Thereafter, the gate electrode 20 is formed on the prepared gate insulating film 18 to construct the semiconductor structure of the present invention.

### EXAMPLES

Hereinafter the present invention will be explained further in detail using particular examples; however, the present invention is not limited to the particular examples described herein below.

### Example 1

A commercially available as-polished TiO₂ single crystal substrate having Rutile structure (SHINKOSHA CO., LTD.; (110) surface) was subjected to heat treatment under 700 Celsius degrees in the ambient air for one hour to prepare a substrate. The obtained substrate was observed by an Atomic Force Microscope (AFM; SEIKO INSTRUMENTS INC. SPI3700/SPA300) to examine the surface condition thereof and FIG. 7 shows the resulted AFM image. As shown in FIG. 7, steps and terraces were observed at the surface of the TiO₂ single crystal substrate that used in Example 1. Also as shown in FIG. 7, while step edges having rough structures, a flat surface in the atomic level with a step height of 0.32 nm was obtained.

A source electrode and a drain electrode of 15 nm in thickness were formed on the obtained TiO₂ substrate by a vacuum evaporation method using a vacuum coater (ULVAC VPC-260; ultimate pressure=2.6×10⁻⁴ Pa) with a contact mask. Al metal was used as the electrode material. Thereafter, an amorphous LaAlO₃ insulating layer of approximately 450 nm was deposited by a pulse laser deposition (PLD) method while using a LaAlO₃ single crystal substrate (SHINKOSHA CO., LTD.) as target. The PLD was carried out under the conditions as follows: the deposition temperature=room temperature, the oxygen gas partial pressure=1.3 Pa, the pulse laser=KrF excimer laser (248 nm wavelength; LAMBDA PHYSIK CO., TD.; COMPEX102) with 4 Hz, output energy=2.8 J/cm² and laser pulse numbers=60000 shots. An Al electrode of 15 nm in thickness was formed on the prepared insulating layer by a vapor deposition method with a mask to provide a field effect transistor. A plurality of the field effect transistor structures was formed with the drain and the source electrodes that are aligned perpendicularly (90 degrees rotation) to each other in order to investigate the anisotropy of the mobility.

FIG. 8 shows the characteristics of the obtained filed effect transistor at room temperature. FIG. 8(a) shows the plot of the current (Ids) flowing through the source—drain electrodes versus the voltage applied between the source—drain electrodes at the various gate voltages, and FIG. 8(b) shows the plot of the current (Ids) flowing through the source—drain electrodes versus the applying gate voltage. As shown in FIG. 8(a), it was shown that the source-drain current Ids was apparently modulated by applying the gate voltage (Vg). Also as shown in FIG. 8(b), it was found that the Ids present to an on-to-off current ratio exceeded an order of 10² in response to on-off switching operation of the gate voltage, and hence the obtained transistor structure could work as a transistor. Further FIG. 8(b) shows that the conductivity of the channel increased due to applying positive bias on the gate electrode, which indicates that TiO₂ functions as a typical n-type channel active layer. Furthermore, the relatively large value of the Ids, that is an order of 10⁻⁸ A at the Vg=0 was observed. Thus it could be said that the field effect transistor obtained in the Example 1 presented the normally-on type characteristic. The mobility at the saturated region, μ^{sat} (mu sat)=0.03 cm²/Vs was obtained from the Vg-Ids characteristic shown in FIG. 8(a).

### Example 2

### Effect of HF Surface Treatment

The commercially available as-polished Rutile type TiO₂ single crystal substrate used in the Example 1 was also used, and the surface thereof was subjected to etching under the condition described in Japanese Patent Laid Open No. 2004-288767, by using 40% hydrofluoric acid solution (WAKO PURE CHEMICAL INDUSTRIES, LTD.; Special Grade) followed by heat treatment under 700 Celsius degrees for one hour to prepare a substrate. FIG. 9 shows the observation of the surface characteristic of the obtained substrate by using the Atomic Force Microscope. As shown in FIG. 9, the surface of the TiO₂ gives well-defined straight step-terrace structures, which indicates the surface was smoothed in the atomic level. A field effect transistor that has an amorphous LaAlO₃ insulating layer of 750 nm in thickness on the obtained TiO₂ substrate was prepared in a similar way as described in Example 1.

FIG. 10 shows the characteristics of the filed effect transistor obtained from Example 2 at room temperature. Among the characteristics shown in FIG. 10, FIGS. 10(a) and (b) correspond the data of a field effect transistor with a channel formed along [001] crystallographic axis, and FIGS. 10(c) and (d) correspond the data of a field effect transistor with a channel formed along [−110] crystallographic axis. In the both of the cases, the on-to-off current ratio of the Ids exceeded an order of the approximately 10² was observed, and the Ids increased together with increasing the gate voltage Vg, exhibiting a typical n-type channel conductivity; the value of the Ids at Vg=0 suggests a normally-on type transistor characteristic. Estimating the mobility at the saturated region from the data shown in FIG. 10(a) and FIG. 10(c), the mobility in the transistor, in which the channel thereof was formed along [001] crystallographic axis, was 0.08 cm²/Vs, whereas the mobility in the transistor, in which the channel thereof was formed along [−110] crystallographic axis, was 0.03 cm²/Vs and the anisotropy in the mobility was observed.

FIG. 11 shows the mobility along with each of the channel direction obtained from the plurality of the prepared field effect transistors. In the FIG. 11, the horizontal axis represents the device number that was assigned when the plurality of the semiconductor devices having different crystallographic axis was formed by using the contact mask, whereas the vertical axis represents the mobility. As shown in FIG. 11, it could be considered that the mobility shows the anisotropy significantly. The inventors supposed that the anisotropy of the mobility reflects the effective mass difference expected from the band structure of the Rutile structure, and the band structure of TiO₂ is reflected more directly to the anisotropy as the surface condition going to ultra-smooth. Also it was found that because the anisotropy about the channel forming directions was not observed in Example 1, and the mobility along [001] axis in Example 2 was improved to be twice as much as that obtained in Example 1 in which TiO₂ (1 1 0) substrate was used, hence the semiconductor characteristics of TiO₂ strongly depends on the surface treatment.

### Example 3

### Transistor Characteristic Depending on Gate Insulating Film

In a similar way as described in Example 1, Al metal was deposited by the vacuum evaporation method on a Rutile type TiO₂ single crystal substrate (1 1 0) that were ultra-smoothed similarly to the Example 2, to form the source electrode and the drain electrode having a thickness ranging from 15 nm to 20 nm. Thereafter, the gate insulating layer was deposited by using a PLD method. As for the gate insulating layer, first, the first gate insulating layer consisting of MgO (insulating buffer layer) of 1 nm in thickness was deposited by irradiating 500 pluses of laser=KrF excimer laser at the output energy of 3 J/cm², under the condition of deposition temperature=room temperature, and the oxygen gas partial pressure=1.3×10⁻³ Pa using a MgO target in a PLD method. Thereafter, while using LaAlO₃ target (LaAlO₃ single crystal; SHINKOSHA CO., LTD.), the second gate insulating layer of 300 nm in thickness consisting of amorphous LaAlO₃ was formed by irradiating 40000 pulses of laser=KrF excimer laser at output energy=2.8 J/ cm² with the repetition rate of 4 Hz under the condition of deposition temperature =room temperature and the oxygen gas partial pressure=1.3 Pa.

FIG. 12 shows the characteristics of the field effect transistor produced in Example 3. FIG. 12(a) shows the plot of the Ids versus the source-gate voltage, whereas FIG. 12 (b) shows the plot of the Ids versus the source-drain voltage. As shown in FIG. 12(a), it was found that the off-current was able to be reduced as below as an order from 10⁻¹² to 10⁻¹¹ A by using the first insulating layer. The value of the Ids was an order from 10⁻¹² to 10⁻¹¹ A under the 0 V gate bias condition, indicating a normally-on characteristic. Also, even if the switching behavior of the transistor was considered, the on-to-off ratio of the Ids current obtained beyond the threshold voltage was equal or more than approximately 10⁴ and has been improved by approximately 10² times compared with Example 1 and Example 2. The inventors supposed that the result obtained in Example 3 suggested that the charge transfer at the interface between amorphous LaAlO₃ and TiO₂ , could be prevented by inserting the MgO buffer layer between the TiO₂ layer and the amorphous LaAlO₃ layer. Also the mobility at the saturated voltage was obtained to be 0.05 cm²/Vs, which was same degree as that in Example 2.

### Example 4

### Study on TiO₂ Deposited Layer

An Anatase type TiO₂ film of 25 nm in thickness was formed on a commercially available LaAlO₃ single crystal (SHINKOSHA CO., LTD.; (001) surface) by using a PLD method. The PLD film formation conditions were as follows:

<TiO₂ Film (Anatase)>

Target=a sintered compact of TiO₂ (KOJUNDO CHEMICAL LAB. CO., LTD.);

Temperature of substrate during deposition=650 Celsius degrees;

Oxygen gas partial pressure=1.3×10⁻⁴ Pa;

KrF Excimer Laser=output energy of 1.5 J/cm²; repetition rate of 2 Hz; 10000 pulses.

After the film formation, the annealing of 2 hours was subjected thereto under 101.3 kPa and 400 Celsius degrees to use as a substrate.

Thereafter, an Al metal source electrode and an Al metal drain electrode were formed and a LaAlO₃ film (240 nm) was formed by a PLD method in a similar way as described in Example 1, and an Al metal gate electrode was formed in a similar way as described in Example 1 to produce a field effect transistor. The condition of the PLD method during the LaAlO₃ film formation was as follows:

<LaAlO₃ Film>

Target=a LaAlO₃ single crystal substrate (SHINKOSHA CO., LTD.);

Oxygen gas partial pressure=1.3 Pa;

KrF Excimer Laser=output energy of 2.5 J/cm²; repetition rate of 10 Hz; 230000 pulses.

FIG. 13 shows the AFM image of the produced TiO₂ (Anatase:(0 0 1)) film. When the produced TiO₂ (Anatase:(0 0 1)) film was checked by the Reflection High Energy Electron Diffraction (RHEED) image, a 4-fold periodic diffraction image was apparently found; it was suggested that an ultra-smooth single crystalline Anatase (0 0 1) thin film was obtained. FIG. 14 shows the characteristics of the obtained field effect transistors. FIG. 14(a) shows the plot of the current (Ids) flowing through the source-drain electrodes versus the voltage applied between the source-drain electrodes at the gate voltages, and FIG. 14(b) shows the plot of the current (Ids) flowing through the source-drain electrodes versus the applying gate voltage. As shown in FIG. 14(a), the carrier mobility within the linear region was obtained to be approximately 1 cm²/Vs that was relatively high value. The off current was an order of 10⁻⁵ A that is rather high, which indicates a normally-on type characteristic, and the drain current was able to modulate within an order of magnitude or more, by applying the gate voltage, thus the transistor operation was verified even though Anatase type TiO₂ film was employed.

### Example 5

### Effect of Heat Treatment on TiO₂ Deposition Film

An Anatase type TiO₂ film of 25 nm in thickness was formed on a commercially available LaAlO₃ single crystal (0 0 1) by using the PLD method in a similar manner described in Example 4. Thereafter, the obtained material was subjected to heat treatment under 800 Celsius degrees and the ambient air for 2 hours in an electric furnace. When the produced TiO₂ film was checked by RHEED image, a 4-fold periodic diffraction image was apparently found; it was confirmed that a single crystalline Anatase film was obtained. Subsequently, a source electrode and a drain electrode of 20 nm in thickness were deposited by using Al metal, followed by a MgO film of 2 nm and a LaAlO₃ film of 900 nm were deposited to form a gate insulating layer of totally approximately 900 nm in thickness. Thereafter, a gate electrode of 20 nm in thickness was formed with Al metal to prepare a field effect transistor using the TiO₂ film as the channel layer.

FIG. 15 shows the obtained transistor characteristics. FIG. 15(a) shows the plot of the current (Ids) flowing through the source-drain electrodes versus the voltage applied between the source-drain electrodes at the gate voltages, and FIG. 15(b) shows the plot of the current (Ids) flowing through the source-drain electrodes versus the applying gate voltage. As shown in FIG. 15(b), the field effect transistor obtained in Example 5 was obtained to have an on-to-off current ratio exceeded an order of 10³. Also as shown in FIG. 15(b), a pinch-off was apparently appeared, although an off-current was relatively high as approximately 10⁻⁹ A, it was confirmed that a normally-off type transistor operation was presented. Also the mobility at the saturated region was obtained to be 0.06 cm²/Vs.

### Example 6

### Study on Rutile Type TiO₂ (1 0 0) Single Crystal Substrate

A commercially available Rutile type TiO₂ (1 0 0) single crystal substrate was subjected to HF treatment and annealing treatment to form the surface having step-terrace structures in a similar way described in Example 1. FIG. 16 shows the AFM image of the surface of Rutile type TiO₂ (1 0 0) single crystal substrate obtained in Example 6. As shown in FIG. 16, fine step-terrace structures were also observed at the Rutile type TiO₂ (1 0 0) single crystal substrate obtained in Example 6.

A source electrode and a drain electrode of 20 nm in thickness were formed on the Rutile type TiO₂ (1 0 0) single crystal substrate with step-terrace structures by the vapor evaporation method with the mask in a similar way described in Example 1. Thereafter, a LaAlO₃ insulating layer of 480 nm in thickness was deposited by applying a PLD of KrF excimer laser with 2 J/cm², 4 Hz and 100000 pulses under the condition where the deposition rate=0.0048 nm/pulse. A gate electrode was formed on the deposited LaAlO₃ insulating film by a mask method to prepare an anti-staggered field effect transistor.

FIG. 17 shows the characteristic of the field effect transistor obtained in Example 6. FIG. 17(a) shows the plot of Ids (x 10⁻⁶A) (left hand scale) and Vg (V) (right hand scale) while Vd(V) as the horizontal axis. Whereas, FIG. 17(b) shows the mobility in the cases where the channel was formed along [010] or [001] crystallographic axes. As shown in FIG. 17(a), when the Rutile type TiO₂ was used, an on-to-off ratio was approximately 10 and the mobility was approximately 0.06 cm²/Vs; thus it was found that semiconductor characteristic was presented.

Also field effect transistors were produced so that a channel formation direction was parallel to the crystallographic axes [010] and [001] of Rutile type TiO₂ , and the mobility of each field effect transistor was measured. FIG. 17(b) shows the result thereof. As shown in FIG. 17(b), the channel mobility of each field effect transistor was found to present apparent anisotropy; it was suggested that the semiconductor characteristic was presented.

### Example 7

### Study on Rutile Type TiO₂ (1 0 1) Single Crystal Substrate

A study was done as similar to Example 6 by using a Rutile type TiO₂ (1 0 1) single crystal substrate and FIG. 18 shows the result thereof. FIG. 18(a) shows the plot of Ids (x 10⁻⁶A) (left hand scale) and Vg (V) (right hand scale) while Vd(V) as the horizontal axis. Whereas, FIG. 18(b) shows the mobility in the cases where the channels were formed along [010] and [−101] crystallographic axes. As shown in FIG. 18(a), when Rutile type TiO₂ was used as a channel, an on-to-off characteristic was obtained to be equal or more than 10², which indicates excellent result. On the other hand, the mobility was approximately 0.01 cm²/Vs that is smaller than that of the Rutile type TiO₂ (1 0 0) shown in FIG. 17. Also FIG. 18(b) shows the large difference of mobility about channel directions about crystallographic axis was not observed. The inventors supposed that the absolute value of the mobility is small.

### Example 8

### Study on Film Formation by Oxygen Gas Partial Pressure Modulation

A field effect transistor using an Anatase type TiO₂ thin film as a channel was prepared as follows:

<Substrate>

A LaAlO₃ single crystal (0 0 1) substrate;

<Anatase Type TiO₂ (0 0 1)>

Deposition temperature: 650 Celsius degrees;

Oxygen gas partial pressure: 0.133 Pa (1×10⁻³ torr, during annealing for 5 min)/1.33×10⁻⁴ Pa (1×10⁻⁶ torr, during deposition for 3 min);

the film formation during the oxygen gas partial pressure modulation, totally 20 cycles while a pair of deposition and annealing processes was considered to be one cycle;

Laser conditions: KrF Excimer Laser, 1.5 J/cm², 1 Hz, 6000 pulses;

Thickness: 20 nm;

HF treatment: the same as Example 1;

Annealing after the film formation: oxygen gas pressure=101.325 kPa, 700 Celsius degrees, for two hours.

FIG. 19 shows the timing chart of the film formation by the oxygen gas partial pressure modulation, and the conditions of the film formation rate. During the depositing duration shown in FIG. 19, a TiO₂ film was grown by 1 nm (the deposition rate of approximately 0.333 nm/min).

FIG. 20 shows (a) the Reflection High Energy Electron Diffraction (RHEED) image, and (b) the AFM image of surface, of Anatase type TiO₂ (0 0 1) produced by the oxygen gas partial pressure modulation film formation method. As shown in FIG. 20(a), the produced TiO₂ film apparently shows a 4-fold periodic diffraction image that is proper to Anatase type TiO₂ (0 0 1). As shown in FIG. 20(b), it was found that an ultra-smooth single crystal Anatase (0 0 1) thin film with step-terrace structures was obtained.

<Field Effect Transistor>

An Al metal film of 12 nm was deposited on the above described Anatase type TiO₂ (0 0 1) single crystal film by using a mask method to produce a source electrode and a drain electrode. A LaAlO₃/MgO gate insulating layer was formed on the produced source electrode and the produced drain electrode by following conditions and a gate electrode of 15 nm was formed on the gate insulating layer by using the mask method.

Laser conditions: KrF Excimer laser, 2 J/Cm²;

Deposition temperature=room temperature;

Oxygen gas partial pressure=1.33 Pa;

MgO: 10 Hz, 10000 pulses;

LaAlO₃: 15 Hz, 200000 pulses;

Thickness of the gate insulating film: 600 nm

<Characteristics of Field Effect Transistor>

Characteristics of the produced field effect transistor was measured in a similar way described in Example 1, and FIG. 21 shows the results thereof. FIG. 21(a) shows Ids-Vg characteristic, whereas FIG. 21(b) shows Ids-Vgs characteristic. As shown in FIG. 21, the produced field effect transistor was normally-off, an on-to-off characteristics was excellently exceeded an order of 10⁵, and the mobility thereof was 0.37 cm²/Vs. That is to say, it was found that an annealing of the Anatase type TiO₂ (0 0 1) single crystal intermittently under different oxygen gas partial pressure enable the channel characteristics thereof to improve. The inventors supposed that the crystalline quality thereof could be improved and a defect free TiO₂ single crystal film could be produce by modulating the oxygen gas partial pressure intermittently during the film formation.

### Example 9

### Comparative Example

By using an only as-polished Rutile type TiO₂ single crystal substrate (a substrate not observing step structures by the AFM), a field effect transistor was produced in a similar way as described in Example 1, and an evaluation thereto was done, however a transistor operation was never conformed in the transistor with only polishing treatment.

As described hereinabove, TiO₂ , was demonstrated to function as the active layer in the field effect transistor by subjecting the surface treatment. As described in Example, since the transistor effect was not observed in the TiO₂ substrate without any surface treatments, TiO₂ may be modified characteristics thereof by the surface treatment, and may give both of normally-on and normally-off type characteristics depending on the gate insulating layer. Also adopting film formation method in which oxygen gas partial pressure was intermittently modulated during the TiO₂ film formation so as to reduce oxygen defect, it was demonstrated that the characteristic of the field effect transistor using the TiO₂ film as the channel could be improved.

FIG. 22 shows the summary of the results obtained in Examples 1-8. As shown in FIG. 22, the field effect transistors using TiO₂ as the active layer according to the present invention could drive excellent field effect operation, and in the case where Anatase type TiO₂ film was used as the channel, the on-to-off characteristics being equal or more than approximately 10 was demonstrated. As for the mobility, the value of approximately 1 cm²/Vs was demonstrated in Anatase type TiO₂. As for the off-current, while depending on a variety of insulating film, the off-current was varied from the value giving normally-off type characteristic to the value giving normally-off type characteristic. Further, the present invention may apply to either type device structures whether normal-staggered type or anti-staggered type.

As described hereinabove, the present invention is capable of providing a field effect type semiconductor device and a method for producing thereof, and since a field effect characteristic thereof is expected to obtain without any optical shield layers, it is thought that the present invention is capable of providing the semiconductor device with a novel structure which is possible to apply for extensively wide use, especially use requiring a large area and an optical characteristic.

### BRIEF DESCRIPTION OF THE DRAWINGS

FIG. 1 shows the structure of the first embodiment of the semiconductor device according to the present invention.

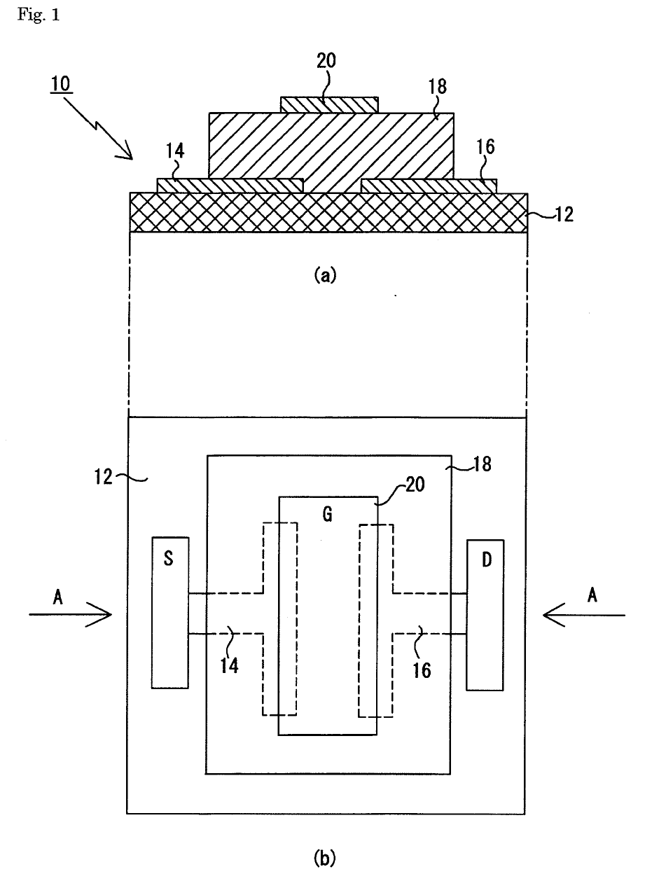

FIG. 2 shows the second embodiment of the semiconductor device according to the present invention.

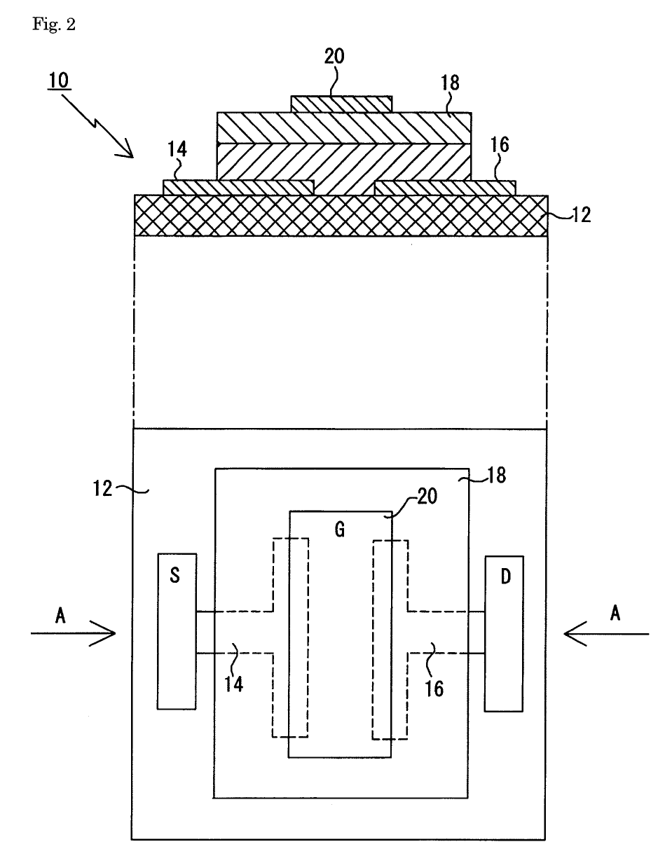

FIG. 3 shows the third embodiment of the semiconductor device according to the present invention.

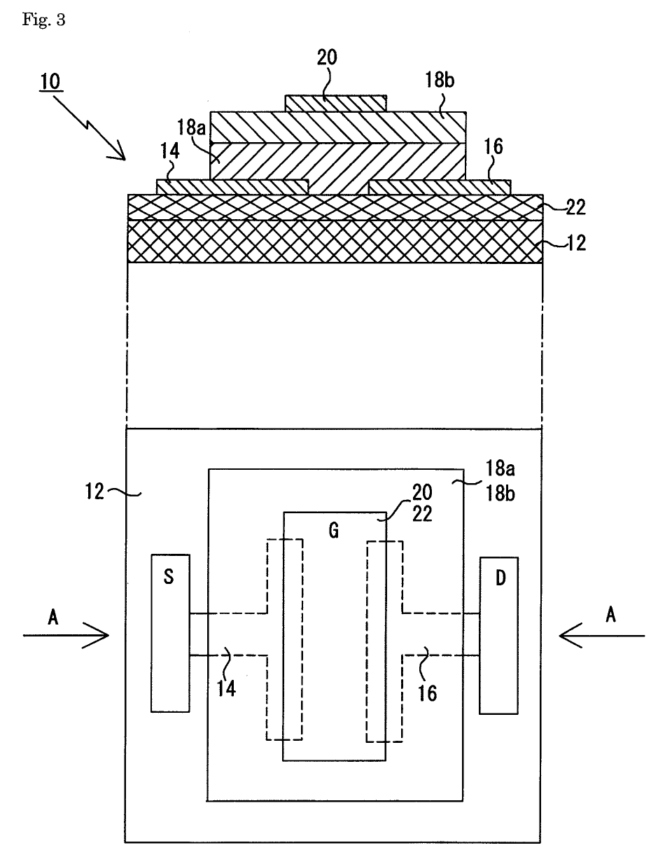

FIG. 4 shows the first embodiment of the production method of the semiconductor device according to the present invention.

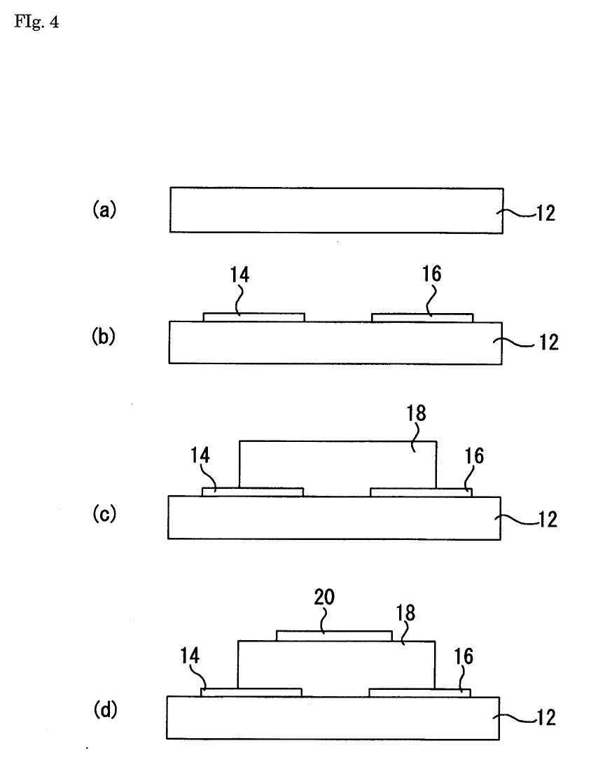

FIG. 5 shows the second embodiment of the production method of the semiconductor device according to the present invention.

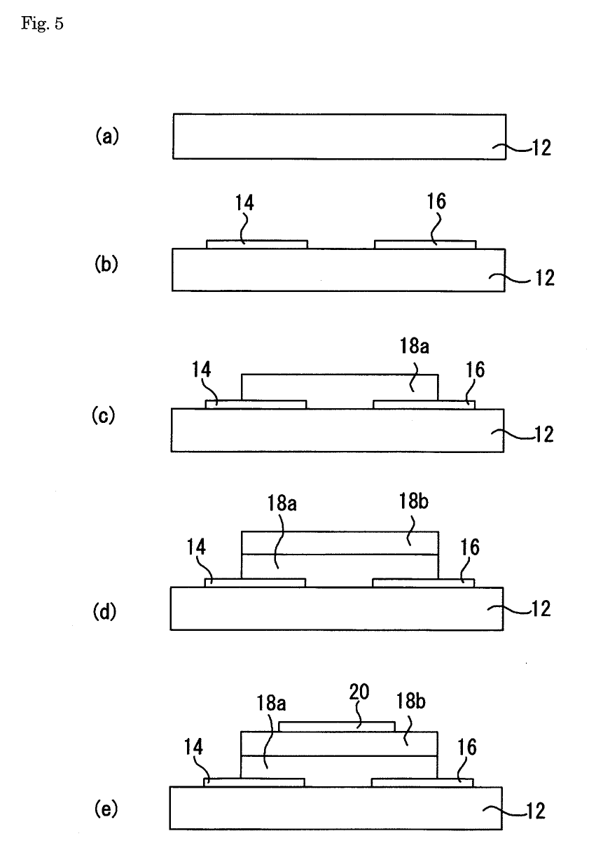

FIG. 6 shows the third embodiment of the production method of the semiconductor device according to the present invention.

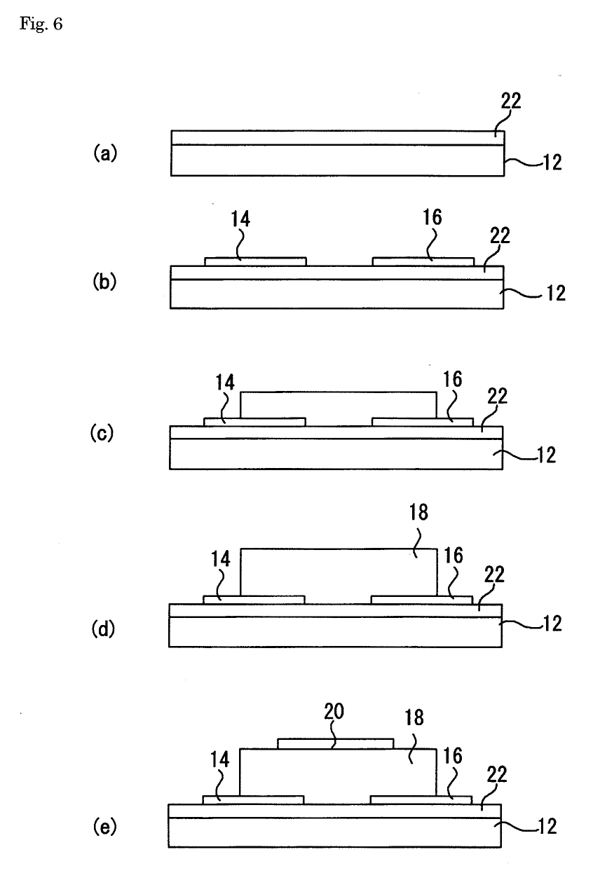

FIG. 7 shows the AFM image of the surface of the TiO₂ single crystal substrate.

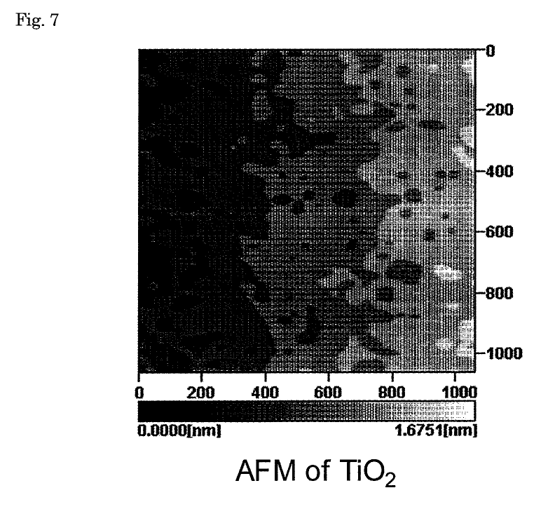

FIG. 8 shows the characteristics of the field effect transistor obtained in the present invention, at room temperature.

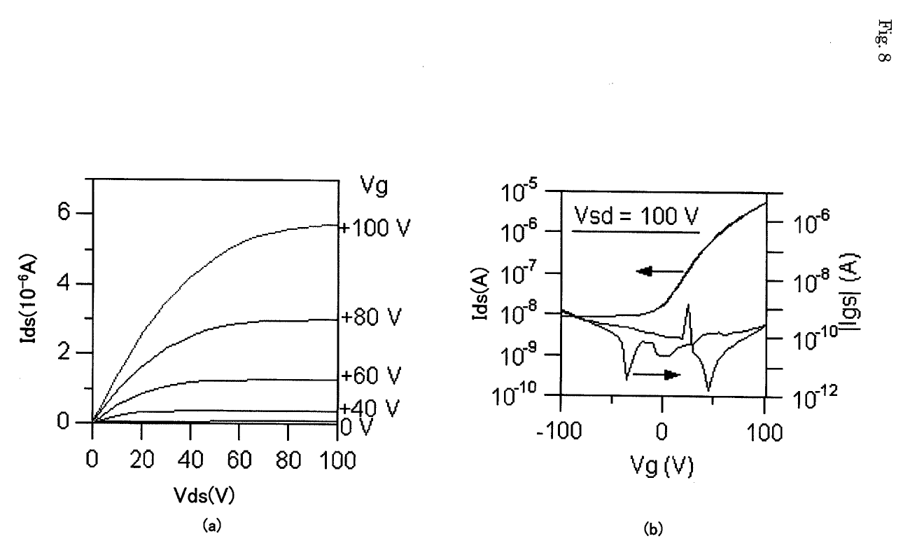

FIG. 9 shows the AFM image of the substrate having step-terrace structures obtained in the present invention.

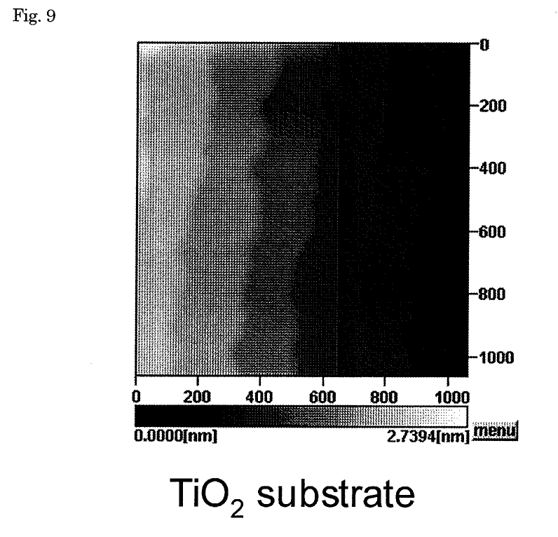

FIG. 10 shows the characteristics of the field effect transistor obtained in the present invention at room temperature.

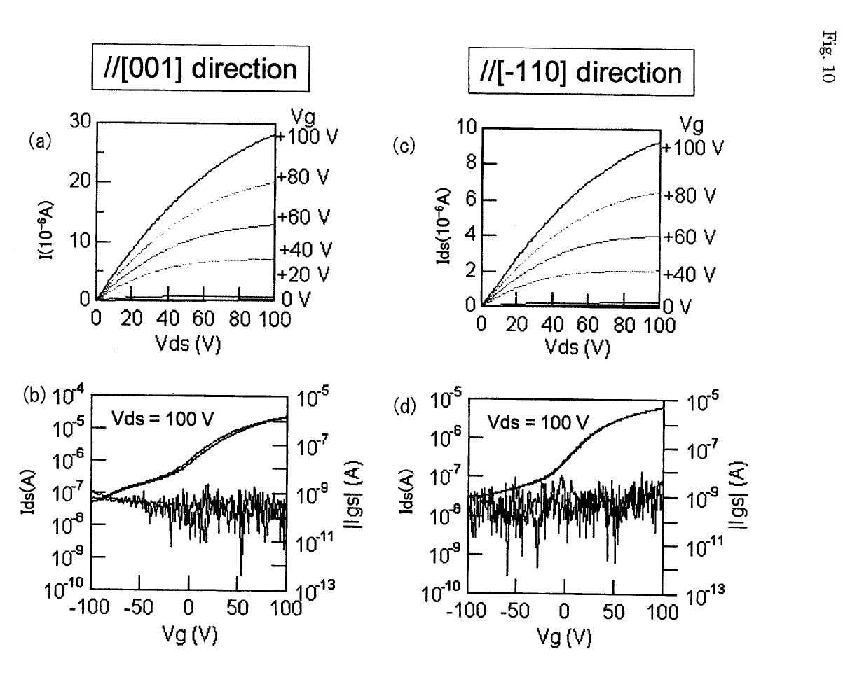

FIG. 11 shows the result of the mobility about each channel direction obtained from the plurality of the produced field effect transistors.

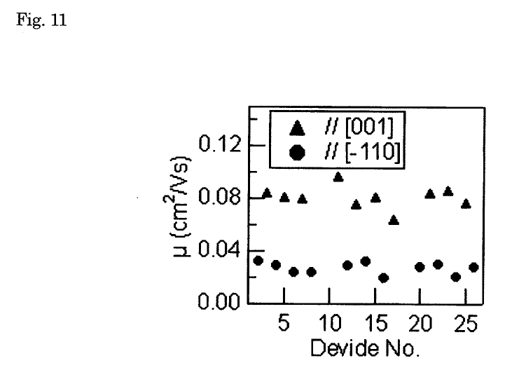

FIG. 12 shows the characteristics of the field effect transistor obtained in the present invention.

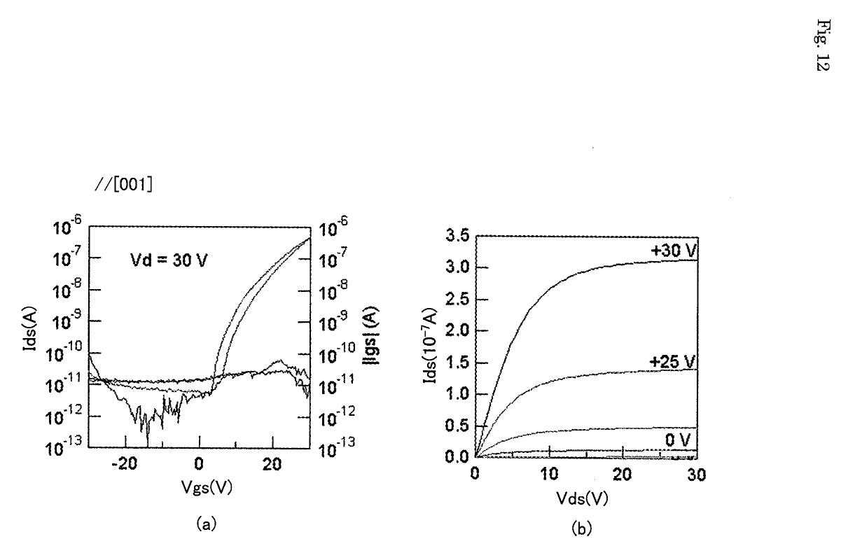

FIG. 13 shows the AFM image of produced TiO₂ (Anatase: 0 0 1) film.

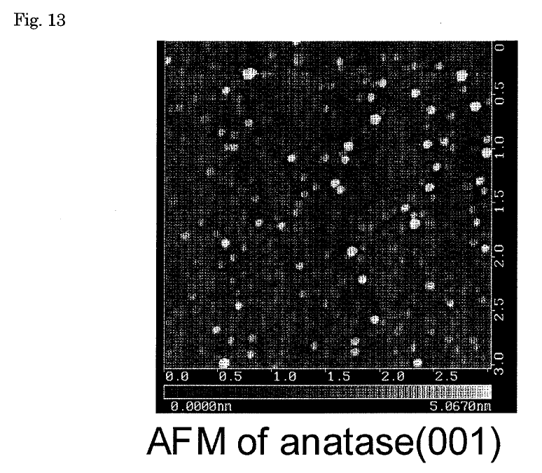

FIG. 14 shows the characteristics of the field effect transistor using the TiO₂ deposited layer (Anatase) as the semiconductor layer.

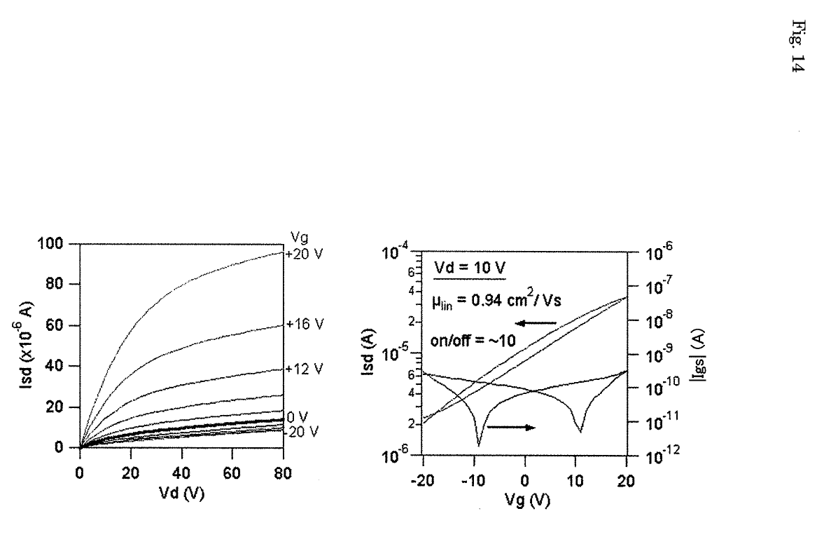

FIG. 15 shows the characteristics of the field effect transistor using the Anatase type TiO₂ film, and the lamination layer of MgO and LaAlO₃ as the gate insulating film.

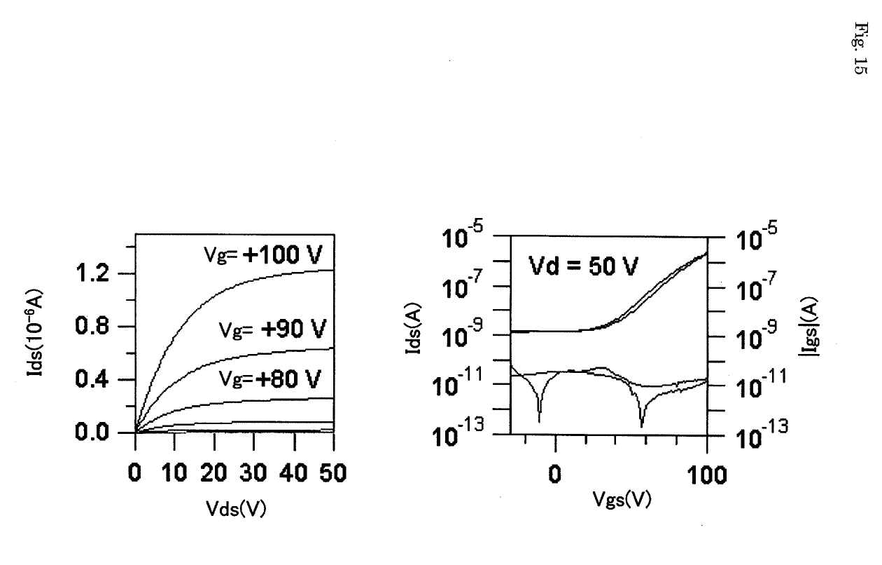

FIG. 16 shows the AFM image of the surface of the Rutile type TiO₂ (1 0 0) single crystal substrate obtained in Example 6.

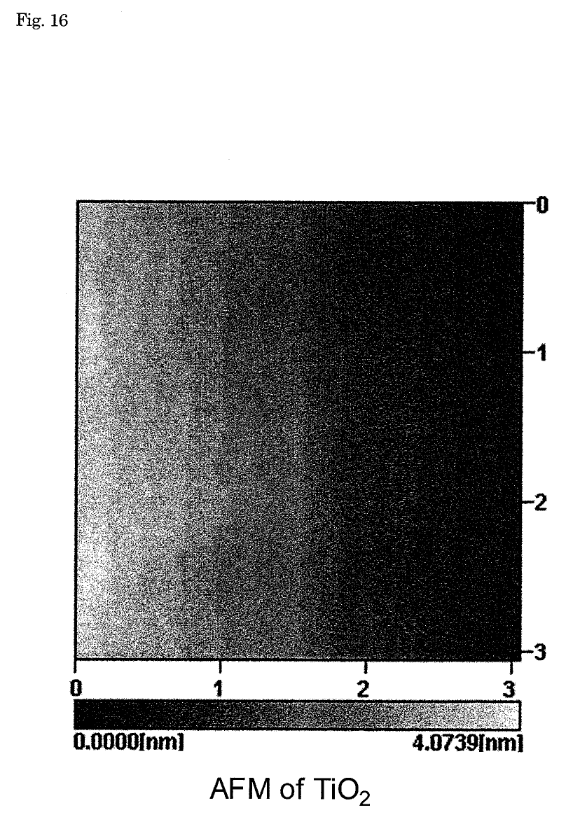

FIG. 17 shows the characteristics of the field effect transistor obtained in Example 6.

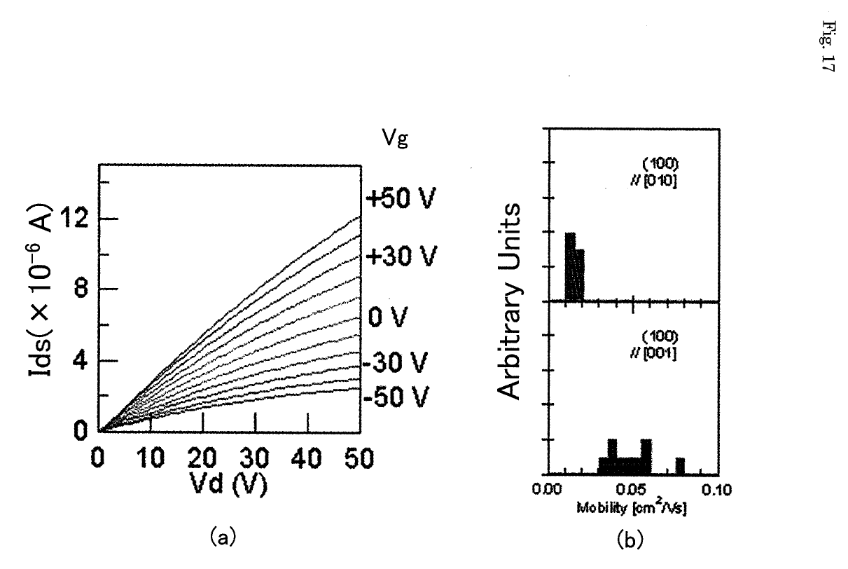

FIG. 18 shows the characteristics of the field effect transistor produced by using Rutile type TiO₂ (1 0 1) as single crystal substrate.

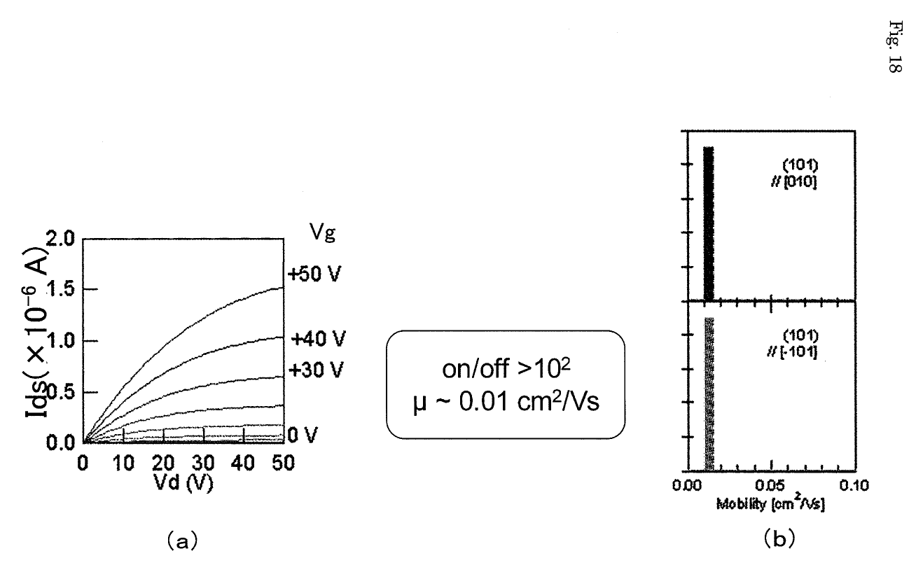

FIG. 19 shows the timing chart and the deposition rate of film formation by the oxygen gas partial pressure modulation according to the present invention.

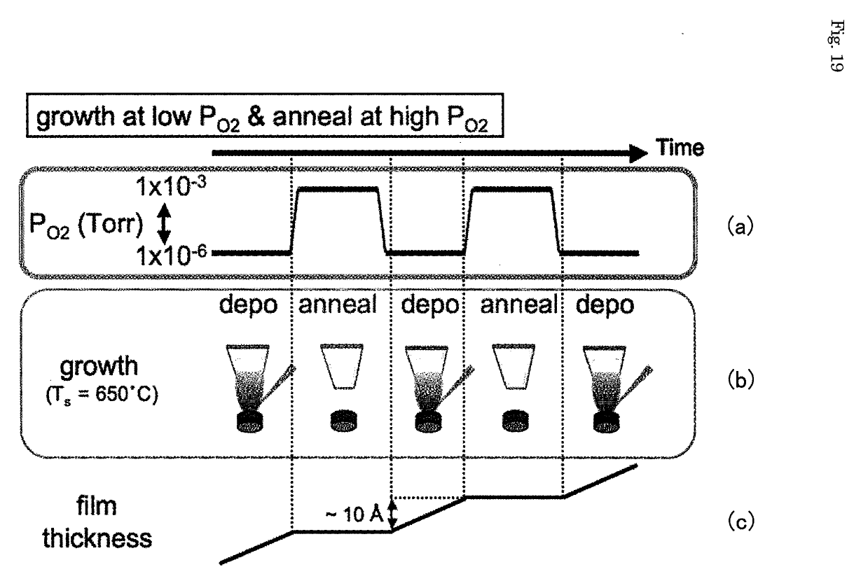

FIG. 20 shows the Reflection High Energy Electron Diffraction (RHEED) image and the AFM image of the surface of the Anatase type TiO₂ (0 0 1) obtained by the oxygen gas partial pressure modulation film formation.

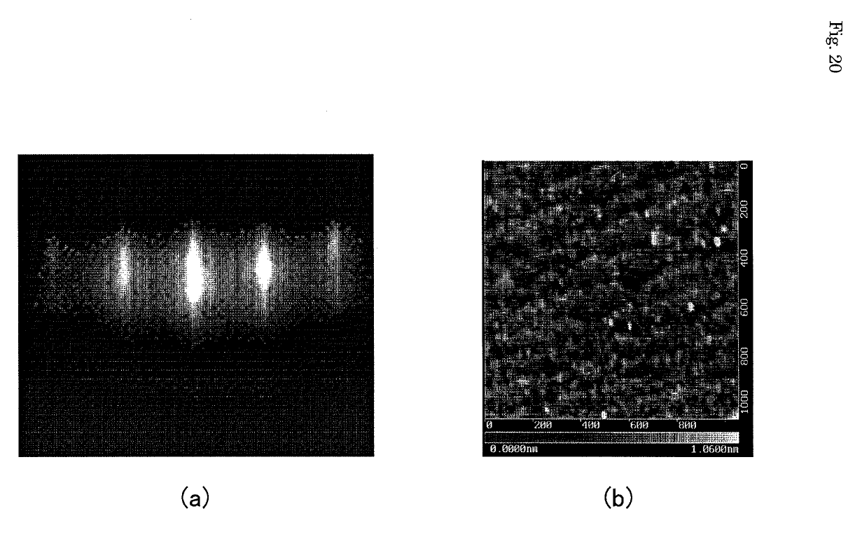

FIG. 21 shows the characteristics of the field effect transistor using the Anatase type TiO₂ (0 0 1) film produced by the oxygen gas partial pressure modulation film formation as the channel.

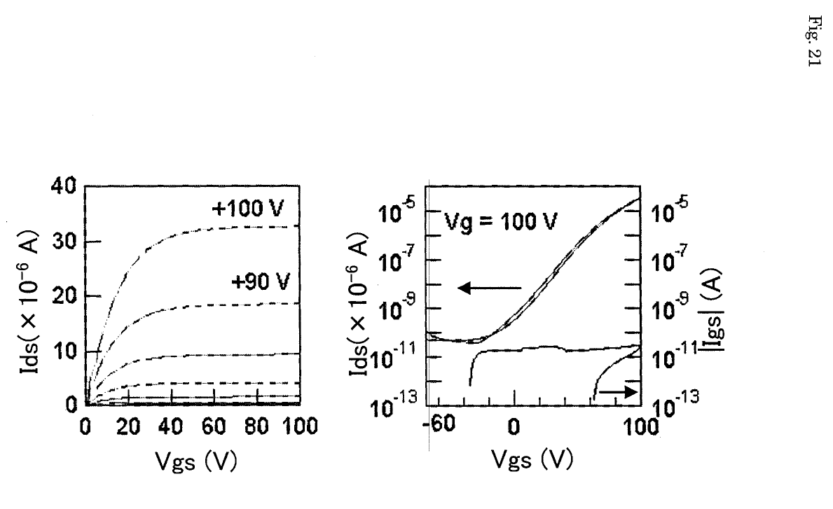

FIG. 22 shows the characteristics of the semiconductor devices obtained in the present invention.

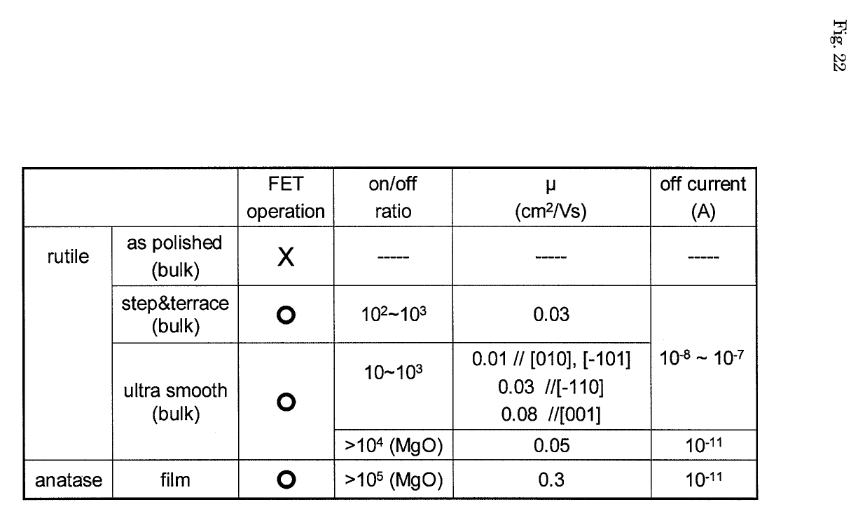

### DESCRIPTION OF NUMERALS

10—semiconductor device

12—substrate

14—source electrode

16—drain electrode

18, 18a, 18b—gate insulating film

20—gate electrode

22—TiO₂ film

1. A field effect type semiconductor device including TiO₂ as an active layer thereof, said semiconductor device comprising:
a gate electrode;
a TiO₂ layer for forming a channel;
a source electrode and a drain electrode being electrically connected to said TiO₂ layer; and
an insulating film formed between said gate electrode and said TiO₂ layer.

2. The semiconductor device of claim 1, wherein said TiO₂ layer includes a Rutile or Anatase structure having a step-terrace structure, or a Rutile or Anatase structure having an ultra-smooth surface thereof.

3. The semiconductor device of claim 1, wherein said TiO₂ layer is a vapor deposition film of TiO₂.

4. The semiconductor device of claim 1, wherein said insulating film is composed from a plurality of oxide layers having different oxygen content ratios each other, and one of said oxide layers has smaller said oxygen content ratio than other being formed adjacent to said TiO₂ layer.

5. A method for producing a field effect type semiconductor device including TiO₂ as an active layer thereof, said method comprising the steps of:
subjecting a surface treatment to a semiconductor layer including TiO₂;
forming a source electrode and a drain electrode being electrically connected to said semiconductor layer subjected the surface treatment;
forming an insulating film on said semiconductor layer; and
forming a gate electrode on said insulating film.

6. The method of claim 5, wherein said insulating film is composed from a plurality of oxide layers having different oxygen content ratios each other, and said step of forming the insulating film comprises a sub-step of forming one of said oxide layers having smaller said oxygen content ratio than other adjacent to said semiconductor layer.

7. The method of claim 5, wherein said step of subjecting the surface treatment comprises a sub-step of providing a step-terrace structure into said semiconductor layer.

8. A method for producing a field effect type semiconductor device including TiO₂ as an active layer thereof, said method comprising the steps of:
depositing a semiconductor layer including TiO₂ on a substrate;
forming a source electrode and a drain electrode being electrically connected to said semiconductor layer;
forming an insulating film on said semiconductor layer; and
forming a gate electrode on said insulating film.

9. The method of claim 8, wherein said insulating film is composed from a plurality of oxide layers having different oxygen content ratios each other, and said step of forming the insulating film comprises a sub-step of forming one of said oxide layers having smaller said oxygen content ratio than other adjacent to said semiconductor layer.

10. A method for producing a field effect type semiconductor device including TiO₂ as an active layer thereof, said method comprising the steps of:
forming a source electrode and a drain electrode on a dielectric substrate;
forming a semiconductor layer including TiO₂ , said semiconductor layer being electrically connected to said source electrode and said drain electrode;
forming a gate insulating film adjacent to said semiconductor layer; and
forming a gate electrode on said gate insulating film.

11. The method of claim 8, wherein said step of forming the semiconductor layer including TiO₂ comprises a sub-step of modulating an oxygen partial pressure intermittently.

12. The method of claim 11, wherein said method comprises steps of;
depositing TiO₂ under the lower oxygen partial pressure condition within said sub-step for modulating the oxygen partial pressure intermittently, and
annealing deposited TiO₂ under the higher oxygen partial pressure condition within said sub-step of modulating the oxygen partial pressure intermittently.
